(19) United States
(12) Patent Application Publication
(10) Pub. No.: US 2013/0143146 A1
(43) Pub. Date: Jun. 6, 2013

(54) HYBRID POROUS MATERIALS AND MANUFACTURING METHODS AND USES THEREOF

(71) Applicants: Hsiao-Feng Huang, Taoyuan City (TW); Chia-Chen Fang, Taipei City (TW); Ping-Chen Chen, Taipei City (TW); Li-Duan Tsai, Hsinchu City (TW)

(72) Inventors: Hsiao-Feng Huang, Taoyuan City (TW); Chia-Chen Fang, Taipei City (TW); Ping-Chen Chen, Taipei City (TW); Li-Duan Tsai, Hsinchu City (TW)

(21) Appl. No.: 13/545,579

(22) Filed: Jul. 10, 2012

(30) Foreign Application Priority Data
Dec. 2, 2011 (TW) 100144311

(51) Int. Cl. B32B 3/26; B32B 27/06; B32B 5/00; B32B 15/08; B32B 5/02; H01G 9/00; B32B 15/14; B05D 5/12; H01G 13/00; C23C 16/50; C23C 16/06; H01M 2/16; D04H 13/00

(52) U.S. Cl. 429/508; 429/145; 428/315.9; 428/315.7; 428/308.4; 442/59; 442/152; 442/108; 427/58; 427/79; 427/115; 427/569; 427/124; 427/126.1; 361/500; 361/502

(57) ABSTRACT

The present disclosure provides a hybrid porous material including a porous material including a microporous polymer film or a non-woven fabric, wherein the porous material has an upper surface and a lower surface; and a continuous inorganic coating covering the upper surface, the lower surface, and surfaces of pores within the porous material. The present disclosure also provides a manufacturing method for the hybrid porous material and an energy storage device including the same.

### CROSS REFERENCE TO RELATED APPLICATIONS

This application claims priority of Taiwan Patent Application No. 100144311, filed on Dec. 2, 2011, the entirety of which is incorporated by reference herein.

### TECHNICAL FIELD

The technical field relates to a hybrid porous material, and more particularly relates to a hybrid porous material suitable for use as a separator and a method for forming the same.

### BACKGROUND

A separator is a porous insulating material used in batteries and other energy storage devices. The main function of a separator is to isolate positive and negative electrodes to prevent short circuit therebetween, while maintaining ionic conductivity. A separator should have good mechanical strength, dimensional stability to temperature, and great stability and resistance to chemicals and solvents used in device systems, as well as flexibility to facilitate manufacturing operations. The separator plays an important role in the lifespan of a battery. Most of the existing separators mainly employ porous polymer films or porous inorganic films. The use of porous polymer films may result in a poor wetting property with an electrolytic solution, thereby deteriorating the ionic conductivity and other performances of batteries. This poor wetting property may be overcome by using a porous inorganic film alone, but a friability issue may be present, and the separator may fail to close its pores at elevated temperatures to provide the shutdown function.

Accordingly, what is needed in the art is a material which can be used as a separator to have both superior mechanical properties of a polymer film and superior wetting capability of an inorganic material.

### BRIEF SUMMARY

The disclosure provides a hybrid porous material, including a porous material including a microporous polymer film or a non-woven fabric, wherein the porous material has an upper surface and a lower surface; and a continuous inorganic coating covering the upper surface, the lower surface, and surfaces of pores within the porous material.

The disclosure also provides an energy storage device, comprising the separator comprising the hybrid porous material.

The disclosure further provides a manufacturing method for the hybrid porous material, comprising providing a porous material comprising a microporous polymer film or a non-woven fabric, wherein the porous material has an upper surface and a lower surface; and subjecting the porous material to a dry coating process to form a continuous inorganic coating on the upper surface, the lower surface, and pore surfaces within the porous material.

A detailed description is given in the following embodiments with reference to the accompanying drawings.

### BRIEF DESCRIPTION OF THE DRAWINGS

FIG. 1 illustrates a hybrid porous material according to the embodiments of the disclosure.

FIGS. 2a-2b illustrate the result of scanning electron microscope (SEM) according to an embodiment of the disclosure.

FIG. 3 illustrates a cross-sectional view of a lithium battery according to an embodiment of the disclosure.

### DETAILED DESCRIPTION

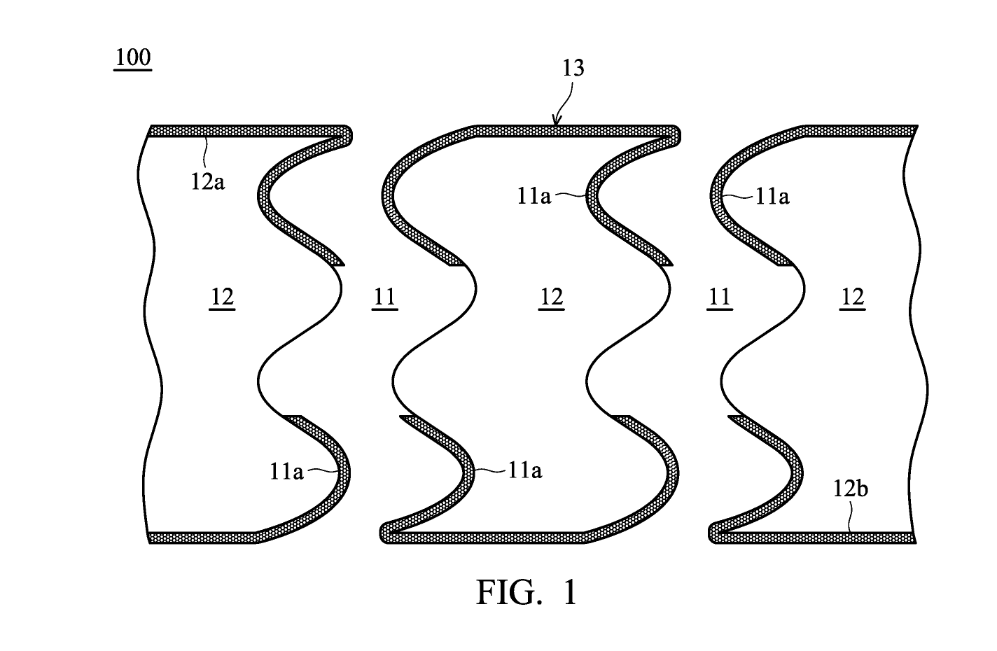

The disclosure provides a hybrid porous material, which can be used as a hybrid separator to have superior mechanical properties of a polymer film and superior wetting capability of an inorganic material, suitable for use in an energy storage device. As shown in FIG. 1, the hybrid separator includes a hybrid porous material 100 comprising a porous material 12. The porous material 12 may include a microporous polymer film or a non-woven fabric. The porous material has an upper surface 12a and a lower surface 12b, wherein the upper surface 12a, the lower surface 12b, and the surfaces 11a of pores within the porous material 12 are covered with a continuous inorganic coating 13. In an embodiment, the continuous inorganic coating 13 may include a carbon-containing, quasi-inorganic coating.

The porous material 12 may include, but is not limited to, polyethylene (PE), polypropylene (PP), polyethylene terephthalate (PET), polyvinylidene fluoride (PVDF), polytetrafluoroethylene (PTFE), polyacrylonitrile, polyimide, polyamide, polyester, natural fiber, or combinations thereof. Note that although the porous material 12 shown in the figures is a single layer structure, it may also be a multi-layer structure including a stack of two or more films, wherein the same or the different materials may be used. The porous material may have a thickness of about 5-80 μm.

The hybrid porous material 100 may have a porosity of about 40-75%, wherein the porosity refers to the percentage of the total porous material volume that is occupied by the plurality of pores.

The continuous inorganic coating 13 may include, but is not limited to oxides of silicon, zinc, zirconium, tin, titanium, barium, aluminum, or combinations thereof. Note that when a coating gas containing an organic functional group, such as alkyl, is employed to form the continuous inorganic coating 13, carbon atoms may be present in the resulting inorganic coating 13, and therefore the continuous inorganic coating 13 may be regarded as a “quasi-inorganic” coating. The continuous inorganic coating may have a thickness of about 1-500 nm. In another embodiment, the continuous inorganic coating may have a thickness of about 2-200 nm. As shown in FIG. 1, the inorganic coating 13 is a continuous inorganic coating, and at least covers the upper surface 12a, the lower surface 12b, and a portion of the surfaces 11a of pores within the porous material 12. In the embodiments of the disclosure, the continuous inorganic coating 13 may completely or partially cover the upper surface 12a and the lower surface 12b, and in addition, the surfaces 11a of pores within the porous material 12 may be completely or partially covered by the continuous inorganic coating 13. The continuous inorganic coating 13 on the surfaces 11a of pores may reach a depth of about 0.01-20 μm. In another embodiment, the continuous inorganic coating 13 on the surfaces 11a of pores may reach a depth of about 0.01-10 μm, from the upper or lower surface to the internal of the porous material.

The disclosure also provides a manufacturing method for the hybrid porous material, including subjecting a porous material to a dry coating process in a plasma reactor with a suitable ratio of a carrier gas which carries a coating gas into the plasma reactor, and coating the porous material by suitable operating conditions. The dry coating process is a one-step process, and is performed through introducing vapor or mist of the target inorganic material to a plasma reactor to coat the surface of the porous material. As shown in FIG. 1, the continuous inorganic coating 13 is formed on the upper surface 12a, the lower surface 12b, and the surfaces 11a of pores within the porous material through a dry coating process. In an embodiment, the dry coating process may be a plasma coating process.

In the manufacturing method for the hybrid porous material of the disclosure, the plasma coating process may be a low pressure plasma process or an atmospheric pressure plasma process.

In the manufacturing method for the hybrid porous material of the disclosure, the dry coating process uses a carrier gas and a coating gas, wherein the carrier gas may include, but is not limited to nitrogen, argon, helium, oxygen, air, hydrogen, or combinations thereof, and the coating gas may include, but is not limited to vapor or mist containing metal elements such as silicon, zinc, zirconium, tin, titanium, barium, or aluminum, or combinations thereof.

More specifically, the coating gas may include, but is not limited to vapor or mist of tetraethoxysilane (TEOS), tetramethoxysilane, hexamethyldisiloxane, (HMDSO), hexamethyl disilazane (HMDS), aluminum butoxide, diethylzin, triethylaluminum, trimethylaluminum, a metal alkyl, titanium tetraisopropoxide, titanium tetrapropoxide, a metal alkoxide, zinc nitrate, aluminum nitrate, metal nitrate, zinc acetate, aluminum nitrate, stannic acetate, metal acetate, zinc sulfate, aluminum sulfate, stannous sulfate, metal sulfate, zinc chloride, zirconium chloride, aluminum chloride, titanium chloride, metal chloride, or combinations thereof.

The disclosure employs an inorganic coating formed by a dry coating process to improve the wetting capability and ionic conductivity of a separator to electrolytic solutions, thereby improving the performance of an energy storage device with a simple process in the absence of a binder.

The hybrid porous material of the disclosure can be used as a separator in an energy storage device, wherein the energy storage device comprises, but is not limited to a lithium battery, a fuel cell, or a super capacitor.

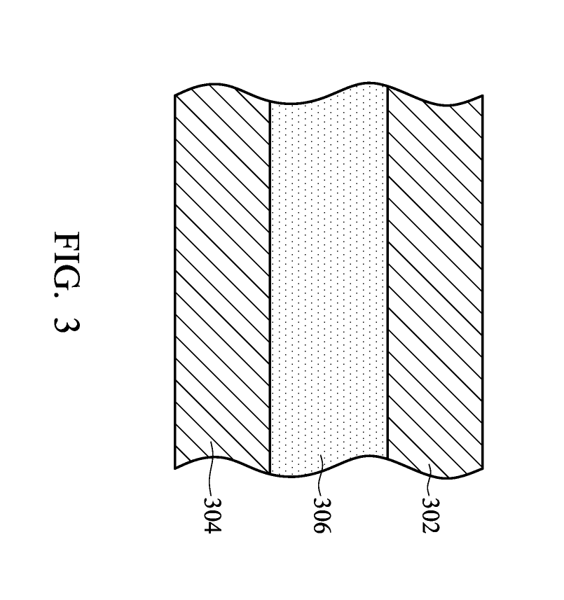

FIG. 3 illustrates a cross-sectional view of a lithium battery according to an embodiment of the disclosure. The lithium battery comprises a pair of a positive electrode plate 302 and a negative electrode plate 304. A separator 306 is disposed between the positive electrode plate 302 and the negative electrode plate 304, wherein the separator 306 contains an electrolytic solution therein. In addition, a sealant may be employed to wrap the positive electrode plate 302, the negative electrode plate 304, the separator 306, and electrolytic solution (not shown) contained in the separator 306.

The hybrid porous material of the disclosure provides a hybrid separator having superior mechanical properties of a polymer film and superior wetting capability of an inorganic material. The surface of the porous material is covered by a continuous inorganic coating without using a binder. The process is simple, cost saving, and readily suitable for commercial use.

The making and using of the embodiments of the disclosure are discussed in detail below. It should be appreciated, however; that the embodiments provide many applicable inventive concepts that can be embodied in a wide variety of specific contexts. The specific embodiments discussed are merely illustrative, and do not limit the scope of the disclosure.

### Example 1

A porous separator having a tri-layer structure consisting of polypropylene

(PP)/polypropylene (PE)/polypropylene (PP) (PP/PE/PP) (Celgard 2320; thickness: 20 μm), was subjected to a coating process. A coating monomer, HMDSO, was placed in a gas washing bottle and heated to a temperature of 30° C. The plasma coating process was performed with the following parameters: an operating pressure of 1 atm, a helium flow of 4.91 l/min, a HMDSO steam flow of 2 sccm carried by helium, an RF power of 90 W, a coating period of 15 seconds, and a sample-electrode spacing of 2.1 mm.

The deionized distilled water contact angles of coated and un-coated samples were compared as shown in Table 1. As can be seen, the hydrophilicity increased drastically after the coating process.

TABLE 1
Hydrophilicity of separator

| Sample | Water contact angle |
|---|---|
| Celgard 2320 | 117.4 ± 1.0 |
| Celgard 2320 after plasma coating | 19.2 ± 1.6 |

Meanwhile, wetting capability, ionic conductivity, resistance, and MacMullin# were measured and the results are illustrated in Table 2. Table 3 illustrates the comparative result of wetting capability according to Formula I:

EAA(wt %)=(Weight of separator dipped with electrolytic solution−Weight of un-dipped separator)/(Weight of un-dipped separator) (I)

Apparently, the coated PP/PE/PP tri-layer separator exhibited improved wetting capability, ionic conductivity, resistance, and MacMullin#, over un-coated samples.

TABLE 2
Ionic conductivity of separator

| Sample | Celgard 2320 | Celgard 2320 after plasma coating |
|---|---|---|
| d (μm) | 20 | 20 |
| A (cm²) | 0.17 | 0.17 |
| R (ohm) | 42.0 | 13.8 |
| ρ (mS/cm) | 0.28 | 0.83 |
| MacMullin # | 27.27 | 8.96 |

TABLE 3
Wetting capability

| | Electrolyte |
|---|---|
| electrolyte film | EC/PC/DEC (3/2/5) |
| Celgard 2320 | 51.4 wt % |
| Celgard 2320 after plasma coating | 102.1 wt % |
| Soaking time | 24 hours (retention) |

Ionic conductivity and MacMullin# were calculated by Formula II and III:

ρ=d/(R×A) (II)

MacMullin#=resistance of (electrolyte+separator)/(resistance of electrolyte) (III)

### Example 2

A porous separator having a single-layer structure (Celgard 2500; thickness: 25 μm), was subjected to a coating process. A coating monomer, HMDSO, was placed in a gas washing bottle and heated to a temperature of 30° C. The plasma coating process was performed with the following parameters: an operating pressure of 1 atm, a helium flow of 4.91 l/min, a HMDSO steam flow of 2 sccm carried by helium, an RF power of 90 W, a coating period of 18 seconds, and a sample-electrode spacing of 2.1 mm.

The deionized distilled water contact angles of coated and un-coated samples were compared as shown in Table 4. As can be seen, the hydrophilicity increased obviously after the coating process.

TABLE 4
Hydrophilicity of separator

| Sample | Water contact angle |
|---|---|
| Celgard 2500 | 118.7 ± 1.5 |
| Celgard 2320 after plasma coating | 22.2 ± 4.7 |

Further, a transmission electron microscope (TEM) confirmed the presence of a coating film on the external surface as well as the internal (pore) surface of the PP separator, wherein the thickness of the coating film was about 20-30 nm.

### Example 3

A porous separator having a tri-layer structure consisting of polypropylene (PP)/polypropylene (PE)/polypropylene (PP) (PP/PE/PP) (Celgard 2320; thickness: 20 μm), was subjected to a coating process. A coating monomer, HMDSO, was placed in a gas washing bottle and heated to a temperature of 30° C. The plasma coating process was performed with the following parameters: an operating pressure of 1 atm, a helium flow of 8.56 l/min, a HMDSO steam flow of 2 sccm carried by helium, an RF power of 100 W, a coating period of 15 seconds, and a sample-electrode spacing of 2.1 mm.

The deionized distilled water contact angles of coated and un-coated samples were compared as shown in Table 5. As can be seen, the hydrophilicity increased drastically after the coating process.

TABLE 5
Hydrophilicity of separator

| Sample | Water contact angle |
|---|---|
| Celgard 2320 | 117.4 ± 1.0 |
| Celgard 2320 after plasma coating | 30.3 ± 4.5 |

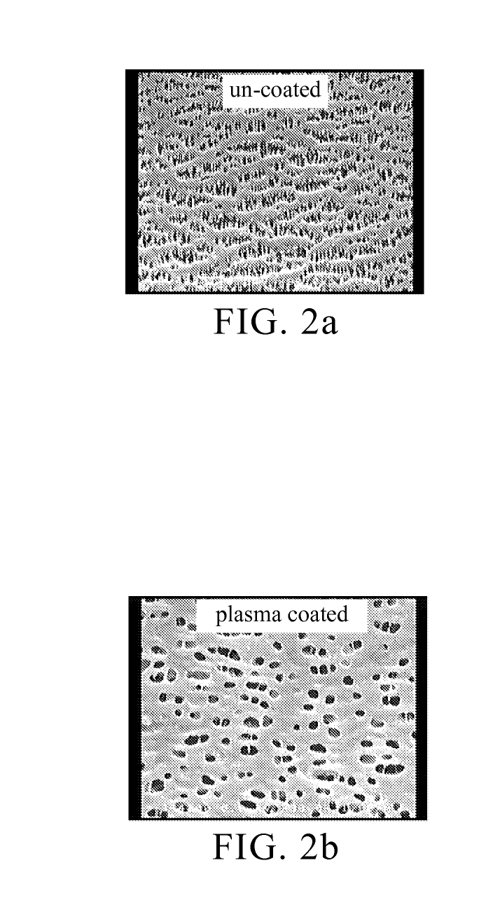

Surface structures illustrated in FIGS. 2a-2b were investigated by a scanning electron microscope (SEM). The result confirmed the presence of a coating film on the external surface of the PP separator, and porosity was still maintained.

While the disclosure has been described in detail and with reference to specific embodiments thereof, it is to be understood that the foregoing description is exemplary and explanatory in nature and is intended to illustrate the disclosure and its preferred embodiments. Through routine experimentation, one skilled in the art will readily recognize that various changes and modifications can be made therein without departing from the spirit and scope of the disclosure. Thus, the disclosure is intended to be defined not by the above description, but by the following claims and their equivalents.

What is claimed is:

1. A hybrid porous material, comprising:
a porous material comprising a microporous polymer film or a non-woven fabric, wherein the porous material has an upper surface and a lower surface; and
a continuous inorganic coating covering the upper surface, the lower surface, and surfaces of pores within the porous material.

2. The hybrid porous material of claim 1, wherein the porous material comprises: polyethylene (PE), polypropylene (PP), polyethylene terephthalate (PET), polyvinylidene fluoride (PVDF), polytetrafluoroethylene (PTFE), polyacrylonitrile, polyimide, polyamide, polyester, natural fiber, or combinations thereof.

3. The hybrid porous material of claim 1, wherein the porous material has a thickness of about 5-80 μm.

4. The hybrid porous material of claim 1, wherein the porous material has a porosity of about 40-75%.

5. The hybrid porous material of claim 1, wherein the surfaces of the pores within the porous material are completely covered by the continuous inorganic coating.

6. The hybrid porous material of claim 1, wherein the surfaces of the pores within the porous material are partially covered by the continuous inorganic coating.

7. The hybrid porous material of claim 1, wherein the continuous inorganic coating comprises oxides of silicon, zinc, zirconium, tin, titanium, barium, aluminum, or combinations thereof.

8. The hybrid porous material of claim 1, wherein the continuous inorganic coating has a thickness of about 1-500 nm.

9. The hybrid porous material of claim 1, wherein the continuous inorganic coating on the surfaces of the pores within the porous material reaches a depth of about 0.01-20 μm.

10. An energy storage device, comprising a separator comprising the hybrid porous material of claim 1.

11. The energy storage device of claim 10, wherein the energy storage device comprises a lithium battery, a fuel cell, or a super capacitor.

12. A manufacturing method for the hybrid porous material, comprising:
providing a porous material comprising a microporous polymer film or a non-woven fabric, wherein the porous material has an upper surface and a lower surface; and
subjecting the porous material to a dry coating process to form a continuous inorganic coating on the upper surface, the lower surface, and surfaces of pores within the porous material.

13. The manufacturing method for the hybrid porous material of claim 12, wherein the dry coating process is a plasma coating process.

14. The manufacturing method for the hybrid porous material of claim 12, wherein the dry coating process uses a carrier gas and a coating gas.

15. The manufacturing method for the hybrid porous material of claim 14, wherein the carrier gas comprises nitrogen, argon, helium, oxygen, air, hydrogen, or combinations thereof.

16. The manufacturing method for the hybrid porous material of claim 14, wherein the coating gas comprises vapor or mist of silicon, zinc, zirconium, tin, titanium, barium, or aluminum, or combinations thereof.

17. The manufacturing method for the hybrid porous material of claim 14, wherein the coating gas comprises vapor or mist of tetraethoxysilane (TEOS), tetramethoxysilane, hexamethyldisiloxane, (HMDSO), hexamethyl disilazane (HMDS), aluminum butoxide, diethylzin, triethylaluminum, trimethylaluminum, a metal alkyl, titanium tetraisopropoxide, titanium tetrapropoxide, a metal alkoxide, zinc nitrate, aluminum nitrate, metal nitrate, zinc acetate, aluminum nitrate, stannic acetate, metal acetate, zinc sulfate, aluminum sulfate, stannous sulfate, metal sulfate, zinc chloride, zirconium chloride, aluminum chloride, titanium chloride, metal chloride, or combinations thereof.
